(19) United States
(12) Patent Application Publication
(10) Pub. No.: US 2012/0176103 A1
(43) Pub. Date: Jul. 12, 2012

(54) Voltage Conversion and/or Electrical Measurements from 400 Volts Upwards

(75) Inventors: Juan Lizarazo, Oakland, CA (US); Ram Rajagopal, Palo Alto, CA (US)

(73) Assignee: VERIVOLT, LLC, Berkeley, CA (US)

(21) Appl. No.: 13/394,146

(22) PCT Filed: Sep. 3, 2010
(86) PCT No.: PCT/US2010/047838

§ 371 Date: Mar. 4, 2012

Related U.S. Application Data
(60) Provisional application No. 61/239,777, filed on Sep. 3, 2009.

(51) Int. Cl. G05F 1/10; G06F 19/00; G01R 19/00; H03H 7/00

(52) U.S. Cl. 323/234; 323/369; 702/64; 324/107

(57) ABSTRACT

A voltage-converter and a signal processing circuit are disclosed. A voltmeter, a power meter and a three-phase meter each including the voltage-converter and the signal processing circuit are disclosed. Methods of making the voltage-converters, voltmeters, three phase meters and power meters, as well as operating and/or using these apparatus are disclosed. Apparatus including feedback paths with at least one voltage-converters, voltmeters, three-phase meters and/or power meters are disclosed.

### CROSS REFERENCE TO RELATED PATENT DOCUMENTS

This patent application claims priority to provisional patent application No. 61/239,777, entitled “Method and Apparatus for Voltage Dividing, Measurement, and/or Use of Voltage Measurements” filed Sep. 3, 2009, which is incorporated herein by reference in its entirety.

### TECHNICAL FIELD

This disclosure relates to a voltage-converter configured to respond to a 400 volt and above input signal at its carrier frequency band, by generating an output signal whose voltage amplitude is less, often much less, than ten percent of the input voltage amplitude at the carrier frequency band and operates with a second non-zero gain for a second distinct frequency band.

### BACKGROUND

### Technical Problems

Before discussing the specifics of the disclosed apparatus, its uses and operations, several terms will be defined. The voltage between two points is the electrical force that drives an electric current between the points, so that a measure of the voltage is in terms of energy per electrical charge.

Electric current will refer to the rate of flow of the electrical charge, which will typically be carried by moving electrons in a power line, which may be a wire or cable. One standard unit for measuring the rate of flow of electric charge is the ampere, which is charge flowing through some surface at the rate of one coulomb per second. The coulomb is a unit of electrical charge and is approximately equal to the charge of 6.24151×10¹⁸ protons or −6.24151×10¹⁸ electrons.

Electrical current flow will be discussed as either Direct Current (DC) or Alternating Current (AC). In DC, the current flow has a fixed direction, whereas in AC the current flow changes direction in an alternating manner.

As used herein, a signal will refer to an electrical signal including a Direct Current (DC) component with a voltage amplitude at a frequency of 0 Hertz and an Alternating Current (AC) component with voltage amplitudes at all non-zero Hertz frequencies. While most of this disclosure will refer to the conditions of the signal in a finite window in time, this detail will not be repeated except where it is specifically useful.

Medium and high voltage AC signals pose several test and measurement problems. As used herein, a medium voltage AC signal has a voltage amplitude of greater than or equal to 400 volts, or equivalently, not less than 400 volts. The voltage amplitude of a high voltage AC signal is not less than 1000 volts.

Electrical signals, particularly AC signals, lend themselves to a frequency based representation. This representation assigns a voltage amplitude at a given frequency, which is then often summed with other voltage amplitudes at other frequencies to approximate the electrical signal. Frequencies are often measured in terms of Hertz (Hz), which is the number of oscillations in the electron charge direction per second.

Here are a couple of examples: A purely DC signal will have a DC voltage amplitude at the frequency of 0 Hz. However, in practice, DC signals may vary over time, indicating that they also have higher frequency voltage oscillations. The DC voltage amplitude will tend to be much larger than the voltage amplitude of these higher frequency components.

An AC signal averaged over time or window of time can be viewed as essentially the voltage amplitude at 0 Hz, or its DC voltage component. An AC signal has a DC voltage amplitude that is lower than the sum of its higher frequency components.

Several circuits will be disclosed that have a transfer function which describe the transformation of the AC input signal to the output AC signal over a range of frequencies. The gain at a given frequency is the ratio of the frequency component of the output signal divided by the frequency component of the input signal.

The transfer function often operates much the same for an input signal within a frequency band. A frequency band refers to a range of frequencies between a low frequency and a high frequency, for example, a frequency band between 55 Hz and 65 Hz. In such situations the transfer function will be considered to have a single gain across the frequency band between 55 and 65 Hz.

One common class of electrical circuits is called a low pass filter. A low pass filter receives one input signal and generates one output signal. The transfer function of the low pass filter has a non-zero gain from 0 Hz to a cutoff frequency (say 65 Hz). This gain progressively declines to close to 0 for higher frequencies. These circuits are called low pass filters because they pass the low frequencies of the input signal to the output signal, while filtering out the higher frequencies.

A voltmeter is often used to measure a voltage drop across an electrical device. In practice, the voltage drop across a device can be measured directly and safely using a voltmeter that is isolated from ground, provided that the maximum voltage capability of the voltmeter is not exceeded.

However, medium and above voltage AC signals are beyond the voltage range of most inexpensive prior art voltmeters. To interface to relatively inexpensive voltmeters requires a voltage divider circuit that can convert the medium and above voltage AC signals into the operating range of the voltmeters. Step-down transformers are often used as voltage dividers that also act as low pass filters.

The signal for a power line has a carrier frequency that carries essentially all of the energy of the power line. Today, a prior art voltmeter is often used to measure the voltage amplitude of the carrier frequency. However, these prior art voltmeters have problems. The step-down transformers of the prior art voltmeters are often very large and expensive. Measurements that require two or more concurrent measurements need multiple step-down transformers. Therefore, it is often impractical to make these measurements.

One example of this problem is in the measurement of the power in an AC signal. This requires knowing both its voltage amplitude, its current amplitude and the phase difference between the voltage and current signals, requiring concurrent measurements of the voltage and the current. One prior art way to measure the current of a power line places a Rogowsky coil near the power line so that it inductively couples to the carrier signal. The output AC signal of the Rugowsky coil is a voltage varying signal that can be measured by the same or a different voltmeter to determine the current. The output AC signal of the Rugowsky coil is also low pass filtered, this time by at least the inductive coupling. Often, the voltage of the AC signal is found by integrating the output signal of the Rogowsky coil. Assume that the measurements of the voltage and current signals are digitized. There are some problems with this approach:
The digitized voltage signals and current signals are both low pass filtered, so that high frequency fluctuations in the power basically cannot be measured.
Additionally, the phase estimate, based upon the digitized voltage and current signals, has no chance of tracking high frequency fluctuations.

Many types of electrical machinery generate small, high frequency signals as components malfunction and/or due to manufacturing defects. Prior art voltage dividers present two main issues when dealing with these fault-related signals:
Step-down transformers suppress higher frequency components through their action as low pass filters.
Voltage dividers scale down fault-related signals as much as they scale down normal operation voltages. This usually places fault-related signals under the intrinsic baseline noise of the monitoring system, thus making them unidentifiable.

Prior art voltage dividers not only scale down the input voltage by a fixed ratio, but also the voltage dividers interfere with the voltage measurement by adding a baseline level of noise intrinsic to the voltage divider. A digitizer connected at the output of the voltage divider also adds noise to signal before it gets digitized. Both of these sources of noise may have a white spectrum that gets added to the voltage divided signal after voltage dividing. So that the noise added by the sensor and the digitizer, gets multiplied by the inverse of the gain of the voltage divider.

As used herein, Root Mean Square (RMS) refers to the square root of the mean square of one signal to another signal, usually within a window of time. Consider the RMS of the difference between to digitized signals aᵢ and bᵢ for a window from 1≦i≦N may be calculated as {square root over ((Σᵢ₌₁^{N}(aᵢ−bᵢ)²)/N)}. The RMS between two continuous signals f and g for a time interval T₁≦t≦T₂ may be calculated as \sqrt{∫_{T}_{₁}^{T}^{₂}[f(t)−g(t)]²/(T₂−T₁)}.

For example, consider a sensor with an input range of +−10 kV, an output range of +−10V, a gain of 1/1000, and an RMS output noise of 4 mV, is connected to a digitizer with an RMS intrinsic noise at its input stage of 3 mV. The total noise that gets digitized is \sqrt{4²+3²}=5 mV, which would appear as 5V=5 mV/gain of noise at the input of the voltage divider.

### SUMMARY OF THE INVENTION

A voltage-converter is disclosed that includes an input coupling to receive an input signal, an output coupling to provide a low voltage signal, and a converter body configured to respond to the input signal based upon a transfer function to generate the low voltage signal. The input signal at a carrier frequency has a voltage amplitude that is not less than 400 volts. The low voltage signal at the carrier frequency may have a voltage amplitude of not more than ten percent of the input voltage amplitude. The transfer function may have distinct gains in at least two separate frequency bands, with the gain at the carrier frequency of not more than ten percent.

The voltage-converter may be configured to measure power lines and/or electrical equipment. The voltage-converter generates the low voltage amplitude at the carrier frequency of not more than ten percent of the input voltage amplitude, and may also provide amplified, rather than suppressed, small signals at higher and/or other frequencies. These amplified, small signals may be used to indicate component malfunctions and/or flaws of the power lines and/or of the electrical equipment.

The voltage-converter may include multiple interchangeable components. These components may be coupled together to create the appropriate transfer function of the voltage-converter. Each of these components may at least partly create the gain in one or more distinct frequency bands. For example, a first component may create a first gain in a first frequency band and a second component may create a second gain in a second, distinct frequency band, for a voltage-converter including them both.

Two separate voltage-converters used to monitor two different equipments, may have different frequency band profiles. In particular, the two implementations may have different higher frequency bands devoted to the detection of different sets of potential failures, while sharing the same gain in the same carrier frequency band.

Even if a higher frequency is shared, the small signals may need a different gain when they are amplified. For example, a first electrical device may have a first small signal in the volt range, whereas a second electrical device may have a second small signal in the millivolt range. The second small signal needs to be amplified by a gain of 1000 to be about the same voltage as the first small signal.

The voltage-converters made from these components provide an advantage by creating specific transfer functions for measuring specific equipment. A component collection of these interchangeable components is also disclosed that provides a valuable resource for technical staff members. They can rapidly reconfigure the voltage-converter using the component collection to inspect and/or troubleshooting equipment with different measurement requirements.

The voltage-converter may have a length that is at most a scale length (Lvd) multiplied by the voltage amplitude of a carrier frequency divided by 10000 volts. Lvd may be no more than 40 centimeters (cm), or 20 cm, or 10 cm, or 6 cm. An outer wall of the voltage-converter may be the length of the voltage-converter. A cylinder-like shape may form some, or all, of the outer wall of the voltage-converter. Coupling a selected combination of the interchangeable components may form at least part of the cylinder-like body for targeting specific equipment.

A signal processing circuit is disclosed and claimed for use with the voltage-converter and may include the following: An analog to digital converter may be configured to receive the low voltage signal as an analog input from the output coupling to create a digital sample. A digital signal processor may be configured to use the digital sample to create a digital reconstruction of the input signal that stimulated the voltage-converter to generate the low voltage signal received by the analog to digital converter. An output device may be configured to respond to the digital reconstruction.

Several examples of the signal processing circuit are disclosed and claimed:
The analog to digital converter may be very simple. The analog to digital converter may respond to the low voltage signal of the voltage-converter as a comparison to further create the digital sample as an in-range indication. In some situations, the analog to digital converter may perform a single comparison against a predetermined and/or set value. The digital signal processor may respond to the digital sample by counting the changes of the in-range indication to create a count as the digital reconstruction. The output device may output this count.
The signal processing circuit may use the digital reconstruction as a representation of one of the frequency bands. The digital reconstruction can also be used as a very accurate representation of the input signal's voltage.
In some signal processing circuits, the output device may include at least one transmitter to send a version of the digital reconstruction. The transmitter may be a radio frequency device, a light frequency device, such as a fiber optic cable driver, and/or a removable device interface such as a Universal Serial Bus (USB) socket. In certain embodiments, wireline protocols such as Ethernet, ICAN and/or SCADA may be further supported.
The signal processing circuit may couple to a single voltage-converter to form one compact unit. This may form and/or extend the outer cylinder wall of the voltage-converter.
The signal processing circuit may include a receiver coupled to the digital signal processor and configured to present a received message to the digital signal processor. The digital signal processor may be further configured to create a digital reconstruction in response to the received message.
For example, the signal processing circuit may respond to the received message by using the digital reconstruction as the count of the in-range indications, which may be performed on a more sophisticated digital sample through range comparisons. Or the signal processing circuit may respond by using the digital reconstruction as a representation of one of the frequency bands as discussed above. Any combination of the digital reconstructions may be transmitted by a transmitter, also in response to the received message.
The signal processing circuit may further include the following: At least two voltage-converter couplings configured to receive separate output AC signals from voltage-converters. An analog multiplexer coupled to the voltage-converter coupling, the analog to digital converter and a selector control. The analog multiplexer may be configured to respond to the selector control by selecting one of the separate low voltage signals to create the low voltage signal presented to analog to digital converter.
The digital signal processor, the receiver, and/or a selector switch may generate the selector control.
Another interchangeable component may include the voltage-converter couplings and the analog multiplexer configured to couple to the analog to digital converter. For example, one component may have two voltage-converter couplings and a second component may have three voltage-converter couplings.

Various process steps are disclosed and claimed for making, operating and/or using one or more of the components, voltage-converters, signal processing circuits and/or voltmeters:
At least two instances of the components may be assembled to create a voltage-converter with a specific transfer function.
The voltage-converter and the signal processing circuit may be coupled to create a voltmeter.
Coupling a field-to-voltage-converter to one of the analog inputs of the analog to digital converter of the signal processing circuit to create a current estimate of a power line inductively coupled to the field-to-voltage-converter. This when combined with the voltmeter may create a power meter by configuring the signal processing circuit to further generate a phase estimate of the power line, and from the voltage estimate, the current estimate and the phase estimate, calculate a power estimate of the power line.
Coupling at least three of the voltage-converters to the signal processing circuit to create a three-phase meter.
Communicating from one voltmeter a parameter of a first input signal to a second voltmeter creating the phase estimate of the input signals. The parameter may be an estimate of one or more of the following: voltage, current, power, power phase and phasor. More than one parameter may be communicated in some embodiments. The voltmeters may be synchronized in time, in some implementations, through the use of a Global Positioning System (GPS) receiver.

The voltage-converter, the voltmeter, the power meter and/or the three-phase meter may be products of the various disclosed process steps.

The voltmeter may be used to make low noise measurements of an input signal. Apparatus are disclosed including at least one power line, at least one plant, a controller and a feedback path coupling to the power line and the controller. The power line may be configured to transmit a power signal with a carrier voltage of not less than 400 Volts in a carrier frequency band. The plant may be configured to respond to at least one control state to generate at least one output signal. The control state and/or the output signal may include the power line.

The feedback path includes at least one sensor coupled to the power line and configured to respond to the power signal to generate a feedback signal presented to the controller. The sensor may include at least one of the voltage-converter, the voltmeter, the power meter and the three-phase meter. The controller is further configured to respond to the feedback signal to at least partly generate the control signal for the plant.

The plant may be configured to perform one or more of the following: Generate the power signal to drive the power line. Transmit the power signal on the power line. Store power from the power signal on the power line. And/or use the power signal to drive at least one machine.

The feedback signal may be based upon at least one of the low-voltage signal, the digital sample, the digital reconstruction, the voltage estimate, the current estimate, the phase estimate, the power estimate and/or one or more of the parameters. Other parameters that may be of value include range and threshold detections or indications and counts of these detections or indications, possibly sampled at specific time intervals.

### BRIEF DESCRIPTION OF FIGURES

FIGS. 1A to 1D show an example of a voltage-converter including an input coupling to a converter body to an output coupling with the converter body providing the means for implementing a transfer function with non-zero gains for multiple distinct frequency bands.

FIGS. 2A and 2B shows examples of the voltage-converters with differing converter bodies implementing different transfer functions with interchangeable components.

FIG. 2C shows an example of the voltage-converter and FIG. 2D shows a graph of the transfer function of the voltage converter of FIG. 2C.

FIG. 3A shows a robot arm beginning the manufacture of a converter body, and

FIG. 3B shows completing the manufacture of the converter body.

FIG. 4 shows a side view of a package for a voltmeter including the voltage-converter coupled to a signal processing circuit.

FIG. 5 shows a schematic block diagram of the voltmeter showing some further details of the signal processing circuit including a analog to digital converter (ADC) and a digital signal processor (DSP).

FIGS. 6 to 8 show examples of the signal processing circuit.

FIG. 9 shows a three-phase meter including at least three of the voltage-converters coupled to the signal processing circuit.

FIG. 10A shows an example of the voltmeter and the signal processing circuit further including multiple voltage-converter couplings configured to receive separate low voltage signals. In certain embodiments, the voltmeter may operate as the three phase meter of FIG. 9.

FIG. 10B shows another example of the signal processing circuit configured to receive multiple low voltage signals.

FIG. 11 shows a simplified mechanical diagram of an example of AC power measurement in which a power line is coupled to a power meter that includes an inductive coupling and a voltage coupling to the power line.

FIG. 12 shows a simplified block diagram of the power meter of FIG. 11.

FIGS. 13A to 13D show some examples of the field-to-voltage-converter shown in FIG. 12.

FIG. 14 shows an example of an apparatus including at least one power line, least one plant, a controller and a feedback path coupling to the power line and the controller, with the feedback path including at least one sensor coupled to the power line and may include the voltage-converter, the voltmeter, the power meter and/or the three-phase meter.

FIG. 15 shows some details of the plant of FIG. 14.

### DETAILED DESCRIPTION OF FIGURES

This disclosure relates to a voltage-converter configured to respond to a 400 volt and above input signal at its carrier frequency band, by generating a low voltage signal whose voltage amplitude is less, often much less, is a small fraction of the input signal at the carrier frequency band and operates at a second gain for a second distinct frequency band.

As used herein, a signal is an electrical signal including a Direct Current (DC) component with a voltage amplitude at a frequency of 0 Hertz and an Alternating Current component with voltage amplitudes at all non-zero Hertz frequencies.

The voltage-converter has a transfer function describing the transformation of the input signal to the output signal over a range of frequencies.

The gain at a given frequency is the ratio of the frequency component of the output signal divided by the frequency component of the input signal.

The transfer function of the voltage-converter has distinct gains in at least two distinct frequency bands, one of which will be referred to as the carrier frequency band.

Additional circuitry is also disclosed that uses the output signal to diagnose electrical conditions. This circuitry supports inexpensive and/or very accurate sensors for power lines, power generators, power transmission equipment and electrical machinery.

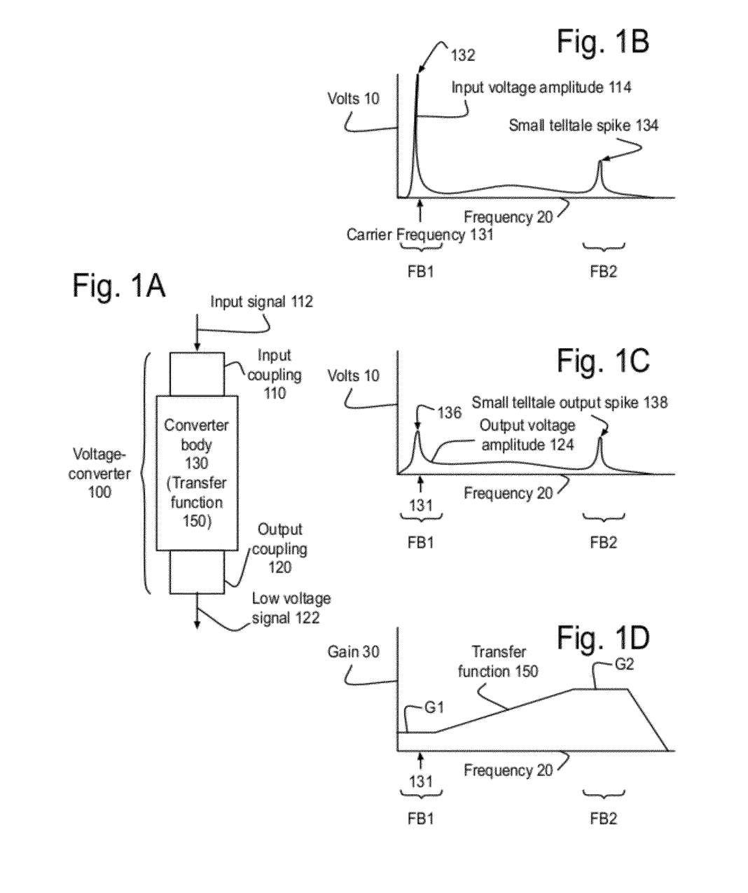

FIGS. 1A to 1D show some aspects of the voltage-converter disclosed herein. FIG. 1A shows an example of the disclosed voltage-converter 100 that includes an input coupling 110 to receive an input signal 112, and through the operation of the converter body 130 implementing a transfer function 150, a low voltage signal 122 is generated as an output at an output coupling 120.

FIGS. 1B and 1C show the input voltage amplitude 114 of the input signal 112 and output voltage amplitude 124 of the low voltage signal 122, each with the vertical axis being volts 10 represented on a logarithmic scale and the horizontal axis being Frequency 20 in units of Hertz (Hz).

FIG. 1B shows a simplified graph of the input voltage amplitude 114 of the input signal 112. The input signal 112 at a carrier frequency 131 has an input voltage amplitude 114 that is not less than 400 volts as the input carrier spike 132 in the first frequency band FB1. The input signal 112 may also have a small telltale spike 134 in a second, separate Frequency Band FB2.

FIG. 1C shows a simplified graph of the output voltage amplitude 124 of the low voltage signal 122 including an output carrier spike 136 at the carrier frequency 131 that is a fraction of the carrier spike 132 of the input signal 112.

FIG. 1D shows an example of a transfer function 150 with a first gain G1 in a first frequency band FB1 that includes the carrier frequency 131 and a second gain G2 in a separate frequency band FB2. G1 may be approximated as the output carrier spike 136 divided by the input carrier spike 132.
For example, suppose that the input carrier spike 132 is about 400 Volts and the output carrier spike needs to be within an acceptable input voltage range of a voltmeter, an Analog to Digital Converter (ADC) or some other measurement device. In some situations, the acceptable input voltage range may have an amplitude of not more than 36 volts, more often 12 volts, possibly 5 volts or lower. In each of these situations the gain G1 of the first frequency band FB1 will be less than 10% for the 36 volts, not more than 3% for 12 volts, and less than 1.25% for 5 volts as the acceptable input voltage range for measurement.

The voltage-converter 100 may be configured to measure power lines and/or electrical equipment. The voltage-converter 100 provides the low voltage amplitude 136 at the carrier frequency 131 within an acceptable input voltage range for measurement with the first gain G1 that is much smaller than 1, and may also provide amplified, rather than suppressed, small signals such as the small telltale output spike 138. This may be done using the second gain G2 greater than G1. The gain G2 may further be greater than one in some situations. These amplified, small signals 138 may be used to indicate component malfunctions and/or flaws of the power lines and/or of the electrical equipment.
Consider the following example of the use of the second gain G2 using FIGS. 1B and 1C. Assume that the voltage converter is coupled to a power line of a machine to be monitored. The machine has a component, that when it begins to wear out, emits the small telltale spike 134 in the second frequency band FB2 shown in FIG. 1B.
Assuming that the acceptable input voltage range is 12 volts, the configuration of the transfer function 150 and of the converter body 130 may need the first gain G1 to be about 12 Volts/400 Volts or 3%. Assume that the telltale spike 134 is not more than 1 volt. To insure accuracy of the readings at the second frequency band, the small telltale output spike should be near 12 volts. So the second gain G2 may need to be about 12 Volts/1 volt or about 1200%.

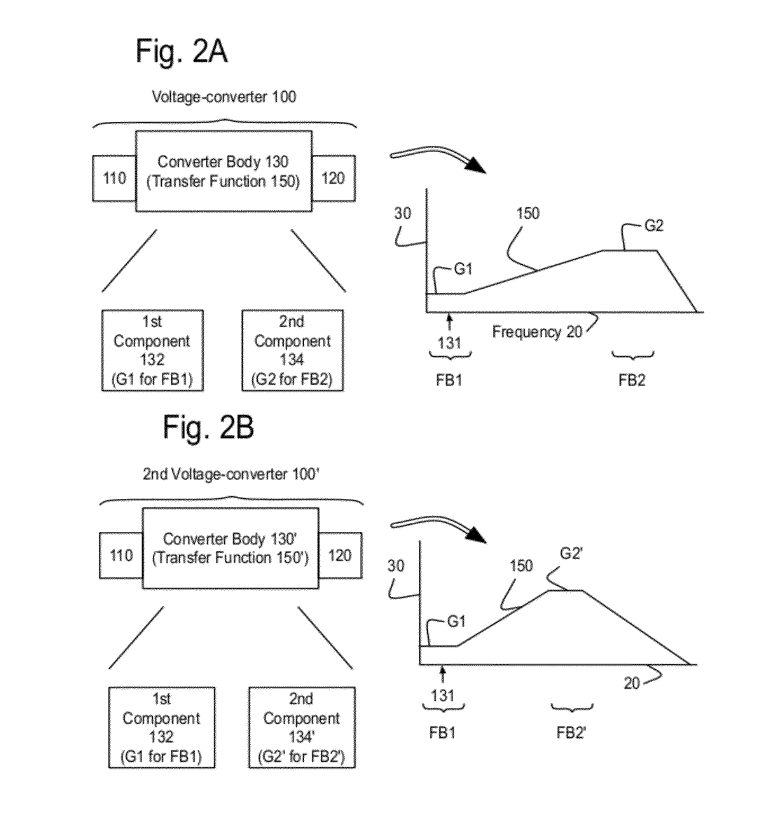

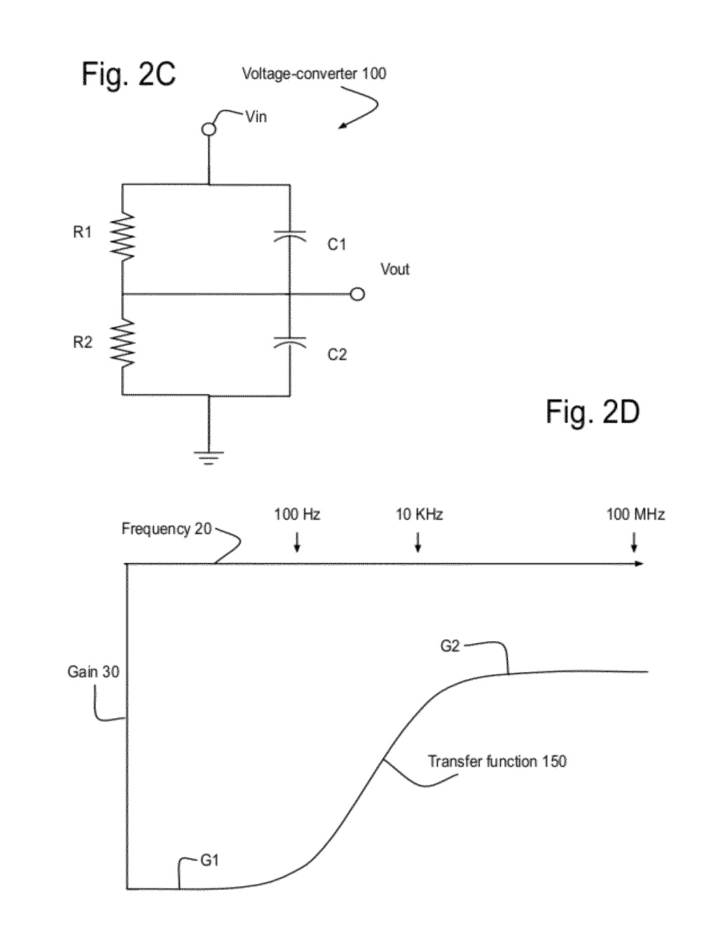

FIGS. 2A and 2B shows examples of two voltage-converters 100 with differing converter bodies 130 and 130′ with differing transfer functions 150 and 150′ made with interchangeable components 132, 134 and 134′. The two transfer functions 150 and 150′ have the same first gain G1 for the same carrier frequency band FB1 and different gains G2 and G2′ for the second frequency bands FB2 and FB2′. In some situations, the second frequency bands FB2 and FB2′ may be the same and the second gains G2 and G2′ may differ. In other situations, the second frequency bands FB2 and FB2′ may differ, but their gains G2 and G2′ may be essentially the same.

FIG. 2A shows the voltage-converter 100, in particular, the converter body 130 may include multiple interchangeable components 132 and 134. These components 132 and 134 may be coupled together to create the appropriate transfer function 150 of the voltage-converter 130. Each of these components may at least partly create the gain in one or more distinct frequency bands. For example, a first component 132 may create a first gain G1 in a first frequency band FB2 and a second component 134 may create a second gain G2 in a second, distinct frequency band FB2, for a voltage-converter 100 including them both.

Voltage converters 100 may have a different frequency band profiles, for example, if they have been configured to monitor different equipment with differing telltale spikes 134 that may be in different frequency bands FB.

FIG. 2B shows a second voltage-converter 100′ used to monitor different equipment from the first voltage converter 100 of FIG. 2A. In particular, the two voltage converters 100 and 100′ may have different higher frequency bands FB2 and FB2′ devoted to the detection of different sets of potential failures, while sharing the same gain G1 in the same carrier frequency band G2.

Even if a frequency band such as FB2 is shared, the small signals may need a different gain G2 and G2′ when they are amplified. For example, a first electrical device may have a first small telltale spikes 134 in the volt range, whereas a second electrical device may have a second small telltale spikes 134′ in the millivolt range. The second small telltale spikes 134 needs to be amplified by a gain of 1000 to be about the same voltage as the first small signal.

The voltage-converters 100 and the converter bodies 130 made from these interchangeable components 132, 134 and 134′ provide an advantage by creating specific transfer functions 150 and 150′ for measuring specific equipment.

FIG. 2C shows an example implementation of the voltage-converter 100 of FIG. 2A and FIG. 2D shows a graph of the transfer function 150 of the voltage converter 100 of FIG. 2C with the horizontal axis representing frequency 20 and the vertical axis representing the gain 30 at the various frequencies plotted. In FIG. 2C, the components have the following values: R1 is 100 Million (M) Ohms, R2 is 100.1 kilo (K) Ohms, C1 is 10 picoFarads (pF), and C2 is 90 pF. FIG. 2D shows the transfer function 150 has a first gain G1 of about 1/1000 from 0 to 100 Hz, then transitions upward to a second gain G2 of about 1/10 above 10K Hz. Note that in this voltage-converter 100, there is no cut-off frequency up to about 100 MHz.

In some embodiments of the voltage-converter 100, multiple identical RC networks may be found in series at branch receiving the input signal 112 to achieve a high voltage rating.

This method of operating a voltmeter may be applied to other sensors, for instance, current sensors, magnetic field sensors, possibly including attenuated MEMS magnetometers, and/or electric field sensors or any other system in which there is a strong signal and a comparatively weak signal that may be separated in terms of their frequency as found in Fourier signal processing and/or some other frame related separation as found in wavelet signal processing.

Multi-Layer Chip Capacitors (MLCC) using C0G/NP0 dielectric may be used in the voltage-converters 100 where capacitances have to be precisely controlled, and special attention is required to meet signal integrity and accuracy goals. C0G/NP0 MLCCs are found in critical applications like RF tuning networks, high fidelity sound quality, detectors for scientific applications, avionics, radar systems, telemetry, communication systems, medical applications, etc. but to date not in voltage measuring applications involving medium and/or high voltage lines.

The voltage-converter 100 may at least one MLCC including a form of C0G/NP0 dielectric. While these capacitors have some excellent performance properties, they have had been restricted to low voltage applications, and in particular, kept away from power line monitoring. The reason for this is that the processes involved in making C0G/NP0 MLCCs are far too expensive to be scaled to make these capacitors match the medium and/or high voltage and high capacitance values that are typically used on power line monitoring systems. In other words, oil-base capacitors used for power line monitoring can achieve relatively medium and/or high voltage and capacitance targets at a much lower cost than a C0G/NP0 MLCC with similar voltage and capacitance values.

However, the inventors have used some new properties of the C0G/NP0 MLCCs to enable the disclosed voltage-converters 100. Recent developments in C0G/NP0 dielectrics had increased the capacitance per unit of volume for C0G/NP0 MLCCs. Using low-noise circuitry decreases the output current requirements throughout the voltage-converter 100. And the use of multiple gains G1 and G2 in separate frequency bands FB1 and FB2 supports digital reconstructions 204 of unparallel accuracy and with new capabilities to resolve small telltale signal spikes 138, which have not been visible in field measurement devices.

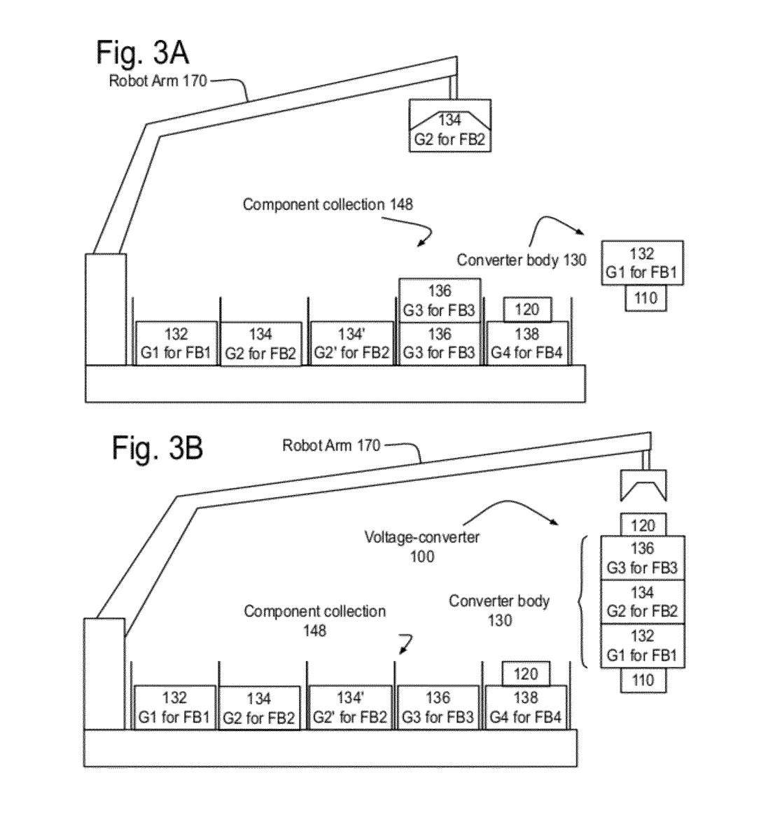

FIGS. 3A and 3B shows a component collection 148 of these interchangeable components 132, 134, 134′, 136 and 138 that provides a valuable resource for technical staff members. They can rapidly reconfigure the voltage-converter 130 using the component collection 148 to inspect and/or troubleshooting equipment with different measurement requirements.

FIG. 3A shows a robot arm 170 beginning the manufacturing of a converter body 130 and FIG. 3B shows the completion of the manufacturing of the converter body 130 with the connecting of the output coupling 120 to the converter body 130. One skilled in the art will recognize that the schematic depiction of the robot arm 170 encompasses not only a single robot arm, but all standard automated assembling devices, which may be used to connect these components 110, 132, 136 and 120, as well as any other combination for manufacturing the converter body 130 and/or the voltage-converter 100.

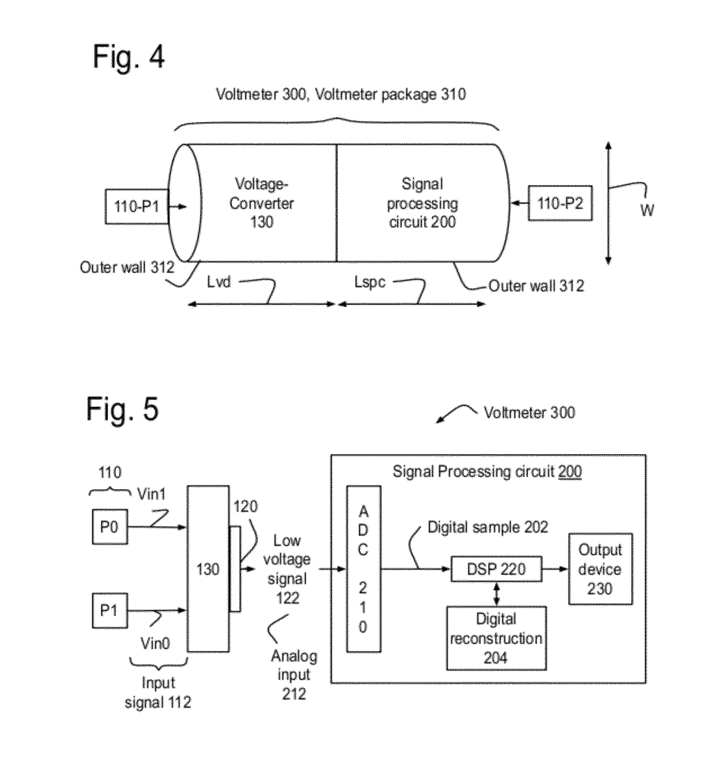

FIG. 4 shows a side view of a package 310 for a voltmeter 300 including the voltage-converter 130 coupled to a signal processing circuit 200. The package for the voltmeter 300 will be referred to as the voltmeter package 310. The voltage-converter 130 may have a length that is at most a scale length (Lvd) multiplied by the voltage amplitude of a carrier frequency divided by 10,000 volts. Lvd may be no more than 40 centimeters (cm), or 20 cm, or 10 cm, or 6 cm. An outer wall of the voltage-converter may be the length of the voltage-converter. A cylinder-like shape may form some, or all, of the outer wall 312 of the voltage-converter 130, which may be shared with the signal processing circuit 200. Coupling a selected combination of the interchangeable components 132, 134, 134′, 136 and/or 138 may form at least part of the cylinder-like voltmeter package 210 for targeting specific equipment.

In certain embodiments of the voltmeter 300, the signal processing circuit 200 may have a length Lspc that is essentially fixed for a wide range of voltage amplitudes Vin at a carrier frequency for which the voltage converter 130 may be configured. For instance, the Lspc may be less than or equal to 20 cm. In certain embodiments, Lspc may less than or equal to 10 cm. Lspc may further be less than or equal to 8.5 cm.

The voltmeter package 310 have an outer wall 312 that form essentially a cylinder as shown in FIG. 4. The width W may be less than or equal to 20 cm, or further, W<=10 cm, or further, W<=6 cm, or still further, W<=5 cm. Note, that W<=10 cm may be written equivalently as W is not more than 10 cm.

A tubular voltmeter package 310 may be advantageous because materials with strong dielectric properties can be easily found as tubes and rods. This simplifies the manufacturing process and makes it very easy to change the voltage rating just by extending the circuit and cutting the outer tube of the package longer. Other solutions often are cast and require a complete redesign of the package for every voltage rating. Using a G10/FR4 material in the package offers tremendous rigidity and robustness to the voltmeter as these materials are incredibly difficult to break, fire retardant and widely available at very low cost.

These voltage-converters 100 require less current because of their use of low noise circuitry with low noise components, low noise architecture, and low noise layout. The inventors recognized that if one cuts by half the noise level of a circuit, there is a decrease in the amount of current required from the input network by half to get the same signal to noise ratio. So, by using very low noise circuitry much lower capacitance values are required in the voltage-converter 100.

In certain embodiments of the voltage-converter 100, when the input voltage amplitude 131 at the carrier frequency 131 may be from 10 KV and upwards, the voltage converter 100 may include only capacitors with little or no temperature dependence , little or no Estimated Series Resistance and/or little or no leakage current. Such a voltage-converter 100 may be fundamentally smaller than prior art voltage dividers using oil filled capacitors and/or transformers. The voltage converter may be about 30 cm long for every 30 kVolts.

FIG. 5 shows a schematic block diagram of the voltmeter 300 of FIG. 4A showing some further details of the signal processing circuit 200. The signal processing circuit 200 may be configured for use with the voltage-converter 130 and may include the following: An Analog to Digital Converter (ADC) 210 may be configured to receive the low voltage signal 122 as an analog input 212 from the output coupling 120 to create a digital sample 202, often creating a new digital sample one to several million times a second. A Digital Signal Processor (DSP) 220 may be configured to use the digital sample 202 to create a digital reconstruction 204 of the input signal 112 that stimulated the voltage-converter 130 to generate the low voltage signal 122 received by the analog to digital converter 210. An output device 230 may be configured to respond to the digital reconstruction 204.

The analog to digital converter 210 may respond to the low voltage signal 122 of the voltage-converter 130 as a comparison to further create the digital sample 202 as an in-range indication.

The DSP 220 may include at least one instance of a computer and/or a finite state machine. As used herein, the computer may include at least one instruction processor and at least one data processor, with each of the data processors instructed by at least one of the instruction processors. As used herein, a finite state machine receives at least one input, may have and alter at least one state and generate at least one output based upon the value of at least one of the inputs and/or the value of at least one of the states.

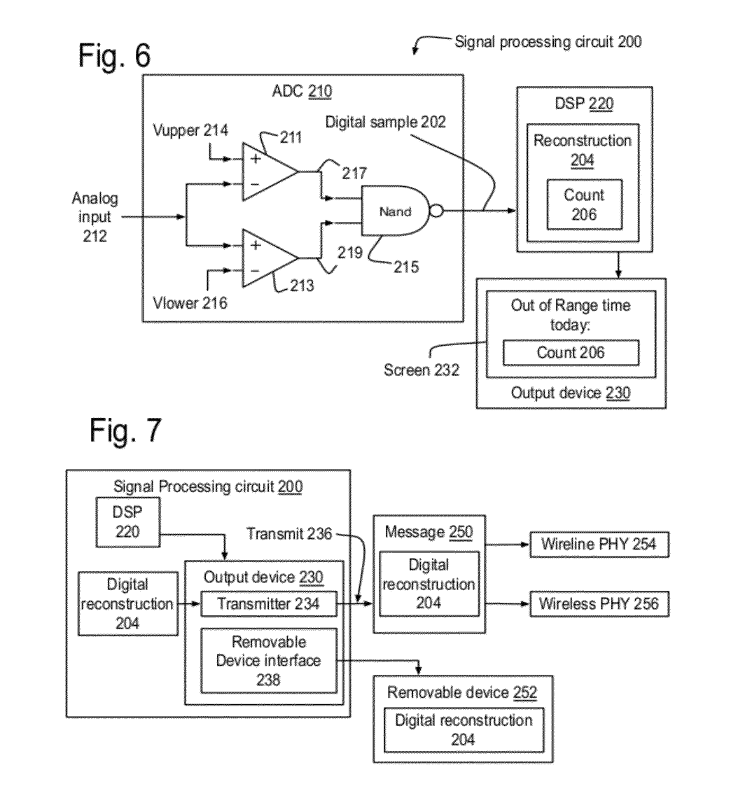

FIG. 6 shows an example of the signal processing circuit 200 generating digital samples 202 as an in-range indication of the analog input 212 that is then counted by the DSP 220 as the digital reconstruction 204 embodied as a count 206 and displayed by the output device 230, possibly on a screen or read-out device. The indication may be asserted by a ‘0’ or by ‘1’ in various embodiments.

For example, the ADC 210 may include two analog comparators 211 and 213, whose outputs will, to simplify this discussion, be assumed to be compatible with a logic gate 215 performing the Nand function. The first comparator 211 receives an upper voltage limit, Vupper 214 on its positive terminal and the analog input 212 on its negative terminal. The second comparator 213 receives a lower voltage limit, Vlower 216 on its negative terminal and the analog input 212 on its positive terminal. Assume that the low voltage signal 122 is below the Vlower 216 voltage, then the first range output 217 of the first comparator 211 is true and the second range output 219 of the second comparator is false, making the digital sample 202 true. In a similar fashion, the following table summarizes the operation of the ADC 210:

TABLE 1
summarizes the operation of the ADC 210 showing that the digital
sample 202 indicates when the low voltage signal 112 as the
analog input 212 is outside a voltage range between Vupper 214
and Vlower 216.

| | 1^{st} range | 2^{nd} range | Digital |
|---|---|---|---|
| Analog input 212, | output | output | sample |
| (Low voltage signal 112) | 217 | 219 | 202 |
| Analog input < Vlower | True | False | True |
| Vlower <= Analog input <= Vupper | True | True | False |
| Vupper <= Analog input | False | True | True |

The DSP 220 may respond to the digital sample 202 by counting the changes of the in-range indication to generate a count 206 as part or all of the digital reconstruction 204. Further, the count 206 may represent an accumulation of how much of the time the low voltage signal 112 is outside the voltage range between Vupper 214 and Vlower 216. This can be an important service metric for some installations and may also be used to show the overall reliability of a generation and/or transmission system or component.

The output device 230 may display the count 206 on a screen 232 for a human to read.

The signal processing circuit 200 may use the digital reconstruction 204 as a representation of one of the frequency bands, such as FB1 or FB2 of FIGS. 1B, 1C and 1D. The digital reconstruction 204 can also be used as a very accurate representation of the input voltage amplitude 114 at the carrier frequency 131 in frequency band FB1 or the small telltale spike 134 in the second frequency band FB2.

FIG. 7 shows an example of a signal processing circuit 200 with the output device 230 including at least one transmitter 234 and/or a removable device interface 238.

The transmitter 234 may be a radio frequency device, a light frequency device, such as a fiber optic cable driver. The transmitter 234 may support wireline protocols such as Ethernet, ICAN and/or SCADA. As shown in the Figure, the DSP 220 may communicate with the output device 230, or more specifically, the transmitter 234, possibly by directing the transmitter 234 to access the digital reconstruction 204 to transmit 236 one or more messages 250 that may communicate a form of the digital reconstruction 204.

The removable device interface 238 may support a Universal Serial Bus (USB) socket and/or a socket compatible with a version of the Institute for Electrical and Electronic Engineers (IEEE) 1394 communications protocol, sometimes referred to as Firewire. The removable device interface 238 may be communicatively coupled to a removable device 252. The digital reconstruction 204 may be loaded and/or updated based upon the state of the digital reconstruction 204 stored and/or maintained in the signal processing circuit 200.

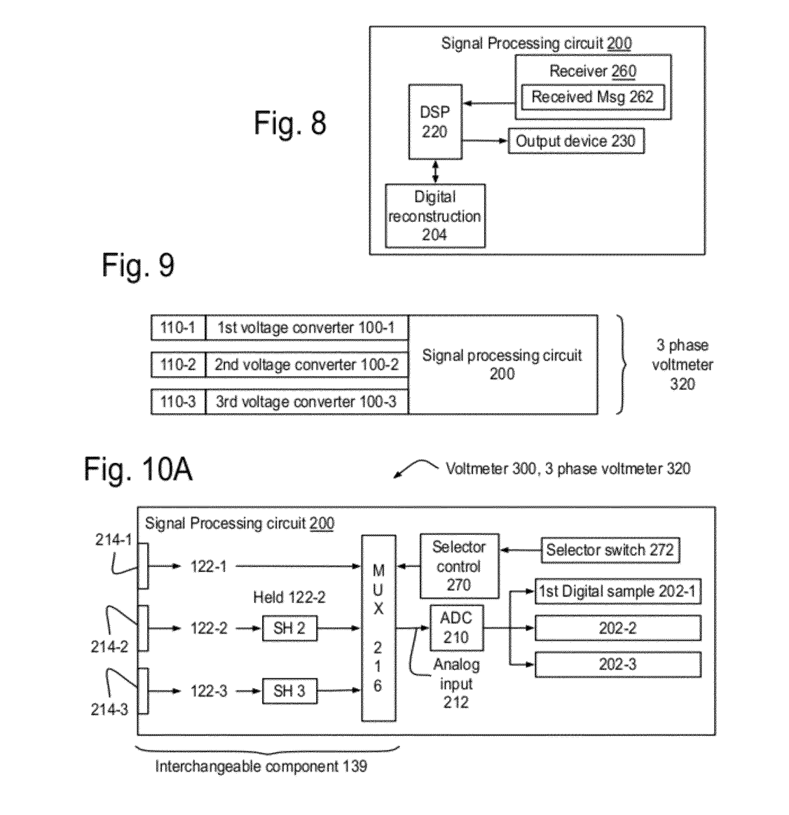

FIG. 8 shows an example of the signal processing circuit 200 including a receiver 260 configured to present a received message 262 to the DSP 220. The DSP 220 may be further configured to create the digital reconstruction 204 in response to the received message 262. The receiver 260 may respond to audio signals, possibly by using a microphone, to implement voice commands possibly through the use of some form of natural language processing, speech recognition and/or voice recognition.

The signal processing circuit 200 may respond to the received message 262 by using the digital reconstruction 204 as the count 206 of the in-range indications of the digital samples 202 as in FIG. 6. Or the DSP 220 may respond by using the digital reconstruction 204 as a representation of one of the frequency bands FB1, FB2 and so on as discussed above. The response to the received message 262 may include the digital reconstructions 204 being transmitted by the transmitter 232 and/or loaded onto a removable device 252 as in FIG. 7 and/or displayed on the screen 232 as in FIG. 6.

FIG. 9 shows a three-phase meter 320 including at least three of the voltage-converters 100 coupled to the signal processing circuit 200.

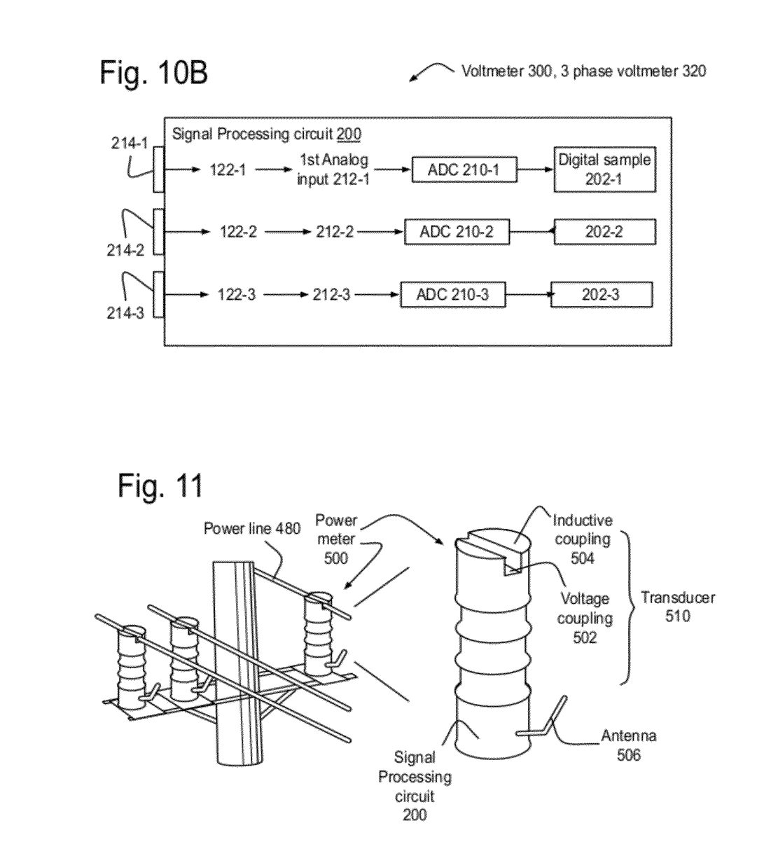

FIG. 10A shows an example of the voltmeter 300 and the signal processing circuit 200 further including at least two voltage-converter couplings 214-1 and 214-2 configured to receive separate low voltage signals 122-1 and 122-2, possibly from separate voltage-converters 100, which are not shown. An analog multiplexer (MUX) 216 may be coupled to the voltage-converter couplings 214-1 and 214-2, the analog to digital converter 210 and a selector control 270. The analog multiplexer 216 may be configured to respond to the selector control 270 by selecting one of the separate low voltage signals 122-1 and 122-2 to create the analog input signal 212 presented to analog to digital converter 210. In some embodiments of the signal processing circuit 200, the analog to digital converter 210 may include the analog multiplexer 216. The digital signal processor (DSP) 220, the receiver 260 as shown in FIG. 8, and/or a selector switch 272 may generate the selector control 270.

By way of further example, FIG. 10A also shows a three phase voltmeter 320 with the signal processing circuit further including a third voltage-converter coupling 214-3 configured to receive a third low voltage signal 122-3 that may be selected by the analog multiplexer 216 to generate the analog input 212 to the analog to digital converter (ADC) 210.

The signal processing circuit 200 may be further configured to generate a first digital sample 202-1 of the first low voltage signal 122-1, a second digital sample 202-2 of the second low voltage signal 122-2 and a third digital sample 202-3 of the third low voltage signal 122-3. The first, second and third digital samples 202-1, 202-2 and 202-3 may be synchronously generated, possibly by the use of Sample and Hold amplifiers.

FIG. 10A also shows the second voltage-converter coupling 215-2 presenting the second low voltage signal 122-2 to a second channel Sample and Hold amplifier (SH 2) to aid the ADC 210 in generating the analog input 212. Similarly, the third voltage-converter coupling 214-3 may also be configured to present the third low voltage signal 122-3 to a third channel Sample and Hold amplifier (SH 3) to further aid the ADC 210 in generating the analog input 212.

Consider using the Sample and Hold amplifiers SH 2 and SH 3 for synchronous generation of the digital samples 202-1, 202-2 and 202-3:
Assume that the ADC 210 is being clocked, and that when the first low voltage signal 122-1 is being converted from an analog input 212, the Sample and Hold amplifiers SH 2 and SH 3 are triggered to capture the second and third low voltage signals 122-2 and 122-3, respectively.
The selector control 270 is then changed to select the held second low voltage signal Held 122-2 generated by the second channel SH 2 as the analog input 212, which the ADC 210 converters into a second digital sample 202-2.
The selector control 270 is then changed to select the held third low voltage signal Held 122-3 generated by the third channel SH 3 as the analog input 212, which the ADC 210 converters into a third digital sample 202-3.
Note that the choice of which of the three low voltage signals 122-1, 122-2 or 122-3 is completely arbitrary, the present example was chosen as possibly being easier to understand, but this example is not meant to limit the scope of the claims.

One skilled in the art will recognize that all the low voltage signals 122-1, 122-2 and 122-3 may be represented to Sample and Hold amplifiers in certain embodiments.

FIG. 10A also shows another interchangeable component 139 that may include the voltage-converter couplings 214-1, 214-2 and 214-3 and the analog multiplexer 216 configured to couple to the analog to digital converter 210 to provide the analog input 212. For example, another version of the interchangeable component 139-2 may have two voltage-converter couplings 214-1 and 214-2.

FIG. 10B shows an example of the signal processing circuit 200 with multiple ADC 210 instances, possibly with one instance for each of the low voltage signals 122-1, 122-2 and 122-3 supporting the synchronous generation of the three digital samples 202-1, 202-2 and 202-3 without the use of any Sample and Hold amplifiers.
The first voltage-converter coupling 214-1 may be configured to provide the first low voltage signal 122-1 as the first analog input 212-1 to the first ADC 210-1, which responds to the first analog input 212 be generating the first digital sample 202-1.
The second voltage-converter coupling 214-2 may be configured to provide the second low voltage signal 122-2 as the second analog input 212-2 to the second ADC 210-2, which responds to the second analog input 212 be generating the second digital sample 202-2.
The third voltage-converter coupling 214-3 may be configured to provide the third low voltage signal 122-3 as the third analog input 212-3 to the third ADC 210-3, which responds to the third analog input 212 be generating the third digital sample 202-3.

In the Examples shown in previous Figures, the ADC instances referenced as 210, 210-1, 210-2 and/or 210-3 may have additional circuit components involved with the sampling of the analog inputs 212, 212-1, 212-2 and/or 212-3.

AC power measurements are of great value in a number of industrial and technical settings, such as determining power line loss and the real-time drain of equipment on AC power supplies and/or power lines.

FIG. 11 shows a simplified mechanical diagram of an example of AC power measurement in which a power line 480 is coupled to a power meter 500 that includes an inductive coupling 504 and a voltage coupling 502 to the power line 480. The power meter 500 further includes a signal processing circuit 200 and a transducer 510 configured to respond to electrical signals generated by the couplings 502 and 504 to create low voltage signals presented to the signal processing circuit 200 to create a voltage reconstruction, a current reconstruction and a phase estimate of the power line 480. The phase may be based upon the voltage reconstruction and the current reconstruction. The signal processing circuit 200 may include a receiver 260 as shown in FIG. 9 and/or a transmitter 234 as shown in FIG. 7, either or both of which may use and/or operate an antenna 506.

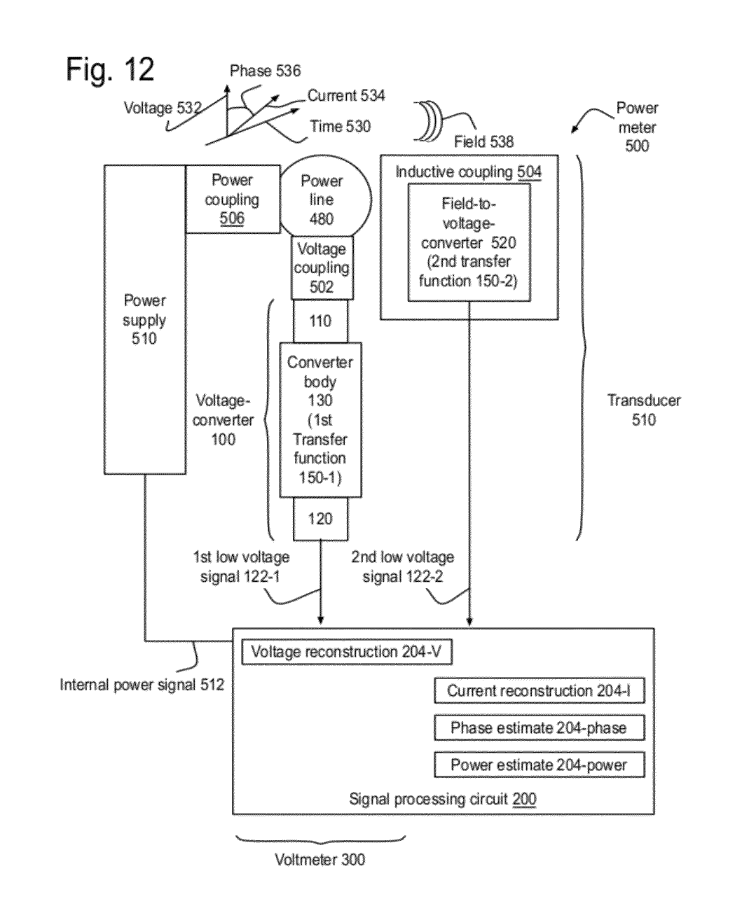

FIG. 12 shows a simplified block diagram of the power meter 500 of FIG. 11 coupled to the power line 480 by the voltage coupling 502, the inductive coupling 504, and possibly a power coupling 506. The voltage 532 and the current 534 vary over time 530 essentially as sinusoidal waves that may be offset from each other by the phase 536. An electro-magnetic field 538 about the power line 480 is largely generated by the current 534.

Coupling the field-to-voltage-converter 520 to one of the analog inputs 212 of the ADC 210 of the signal processing circuit 200 can be used to create a current estimate or reconstruction 204-I of the power line 480 inductively coupled by the electromagnetic field 538 to the field-to-voltage-converter 520. This, when combined with the voltmeter 300 may create the power meter 500 by configuring the signal processing circuit 200 to further generate a phase estimate 204-phase of the power line 480, and from the voltage estimate 204-V, the current estimate 204-I and the phase estimate 204-phase, calculate a power estimate 204-power of the power line 480.

The transducer 510 includes a voltage-converter 100 coupled through the input coupling 110 to the voltage coupling 502, a field-to-voltage-converter 520 and possibly a power supply 510.

The voltage coupling 502 may connect the disclosed voltage-converter 100 through the input coupling 110 to generate the input signal 112 as shown in FIG. 1A. The converter body 130 responds to the voltage 532 of the power line 480 based upon the first transfer function 150-1 to generate the first low voltage signal 122-1 presented at the output coupling 120 to the signal processing circuit 200.

The field-to-voltage-converter 520 uses a second transfer function 150-2 to generate a second low voltage signal 122-2 in response to the electromagnetic field 538 that is essentially determined by the current 534 of the power line 480.

The power supply 510 may use the power coupling 506 to generate at least one internal power signal 512 that may be used within the power meter 500. For example, the internal power signal 512 presented to the signal processing circuit 200 to supply its operational requirements. The power supply 510 may include another instance of the disclosed voltage-converter 100 rather than a less efficient step down transformer.
The power supply may also include one or more batteries so that the signal processing circuit 200 may report its condition during power failures on the power line 480.
The field-to-voltage-converter 520 may also be presented at least one internal power signal 512.
And the power supply 510 may share the voltage coupling 502 with the voltage-converter 100.

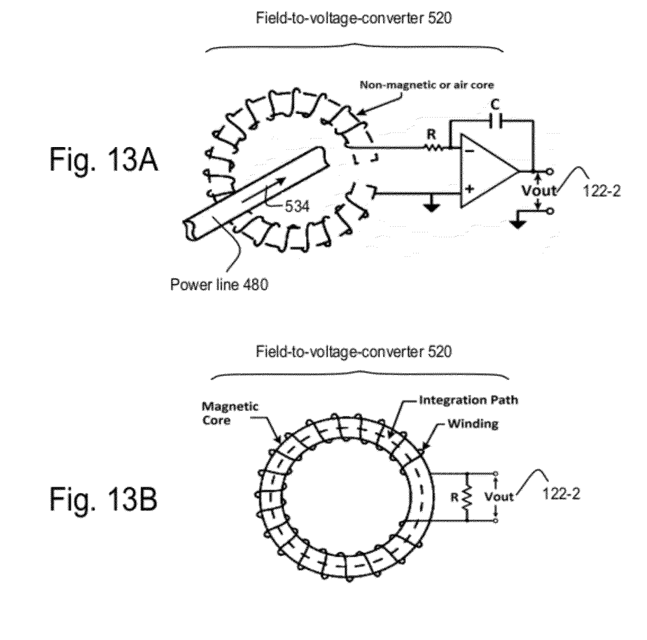

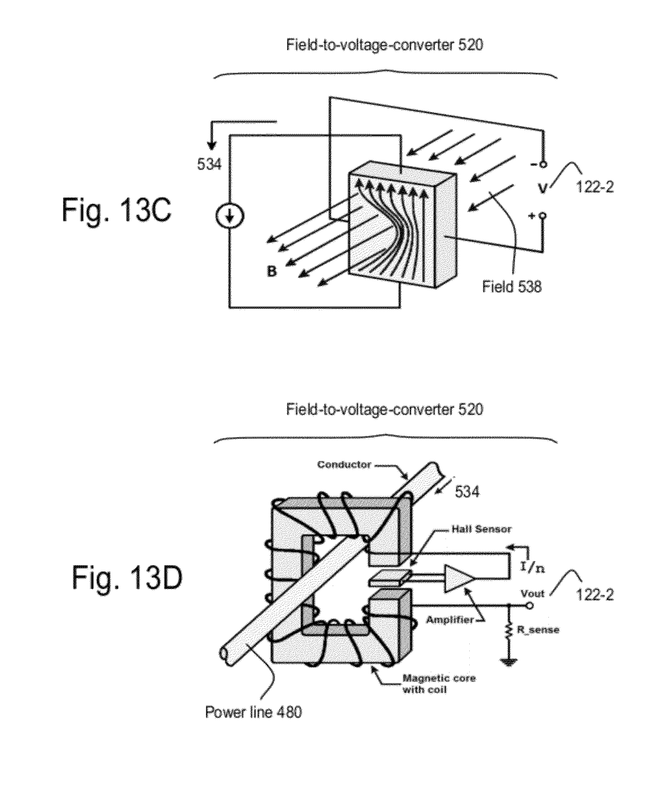

FIGS. 13A to 13D show some examples of the field-to-voltage-converter 520 that may be implemented.

FIG. 13A shows an example of the field-to-voltage-converter 520 as a Rogowski Coil. The field-to-voltage-converter 520 works by measuring the voltage induced in a winding by the time-changing magnetic field 538. The magnetic flux trough the winding is proportional to the magnitude of the current 534, and the voltage at the terminals of the coil is proportional to the time derivative of the magnetic flux. An integrating circuit may be to generate the second low voltage 122-2 of FIG. 12 proportional to the current 534 of the power line 480. The accuracy of Rogowski coils may decrease over frequency due to the parasitic inductance and capacitance of the winding, and its inability to measure DC current. There is also an error associated with the input offset of the integrating IC. The main mechanical issue is the need to loop the coil around the power line. An attractive feature of a Rogowski coil is that it does not suffer from saturation.

FIG. 13B shows an example of the field-to-voltage-converter 520 as a current transformer. Adding a magnetic core to the Rogowski coil of FIG. 13A makes the inductance of the coil be the dominant component when connected in series with a resistive load. For a small enough resistor, the voltage across of it will be proportional to the current 534 in the power line 480. One advantage over a Rogowski coil is that integration is not required, however, errors due to parasitic capacitance and resistance are still an issue. In addition to that, the current transformer's magnetic core present two additional issues: saturation and non-linearity.

FIG. 13C shows an example of the field-to-voltage-converter 520 using a Hall sensor that directly measures the magnetic field 538 next to the power line 480 and correlates it to the line's current 534. Hall sensors use a voltage is induced across a current-carrying conductor under the influence of the magnetic field 538. Disadvantages of this approach are: low accuracy, possible saturation of the Hall sensor, non-linearities, sensitivity to external fields, and its need for a biasing current. An advantage of this approach is the fact that there is no need to loop the sensor around the power line 480.

FIG. 13D shows an example of the field-to-voltage-converter 520 as a compensating current sensor using a Hall sensor. In FIG. 13C the Hall sensor operates in an open loop, and its variability and non-linearity contribute to a substantial inaccuracy in the resulting measurement. However, by putting the Hall sensor in a feedback loop to cancel the field inside a magnetic core, it only has to detect small variations around zero field. The current 534 in the power line 480 can be calculated as the current driven by the amplifier in the feedback loop times the number of turns on the toroid. A clear advantage of this technique is high accuracy. Its main issue is the limitation in bandwidth that comes from the fact that the amplifier in the feedback loop is driving a current through an inductor, which becomes harder as frequency increases.

Multiple instances of the voltmeters 300 may collaborate: Communicating from one voltmeter a parameter of a first input signal to a second voltmeter creating the phase estimate of the input signals. The parameter may be an estimate of one or more of the following: voltage, current, power, power phase and phasor. More than one parameter may be communicated in some embodiments.

The voltmeter 300 may be used to make low noise measurements of an input signal. This will be discussed in terms of an ideal prior art voltage divider and an implementation of the disclosed voltage-converter 100:

Consider the ideal prior art voltage divider to have a uniform gain over its whole bandwidth, whereas actual voltage dividers are more likely to act as low pass filters. To recover the voltage at the input of the divider, the output voltage has to be multiplied by the inverse-gain of the voltage divider. For example, if the output of a voltage divider with a gain of 1/1000 is 5V, this means that the voltage at the input of the voltage divider is 5V*1000=5000V. This also means that the noise added at the output of the divider will show as part of the signal, and will also get multiplied by this same inverse-gain. For example, 1 mV of noise at the output of the voltage divider with a gain of 1/1000, will appear as 1V of noise in the input signal.

The disclosed voltage-converter 100 can greatly reduce this effect. Consider an example voltage-converter 100 with a gain of 1/1000 for a carrier frequency band from 0 to 200 Hz, and a gain of 1/10 for the second frequency band from 200 Hz to 20 MHz. Assume the noise is 1 mV RMS white noise spread evenly from 0 Hz to 20 MHz. In this case, the noise level referenced at the input signal of the voltage-converter is (1*1000*200+1*10*19999800)/20000000 which is about 10 mV.

Although the noise level of the measurement setup is the same in both cases, once the noise is referenced to the input signal, the level of noise in the second example is 100 times smaller.

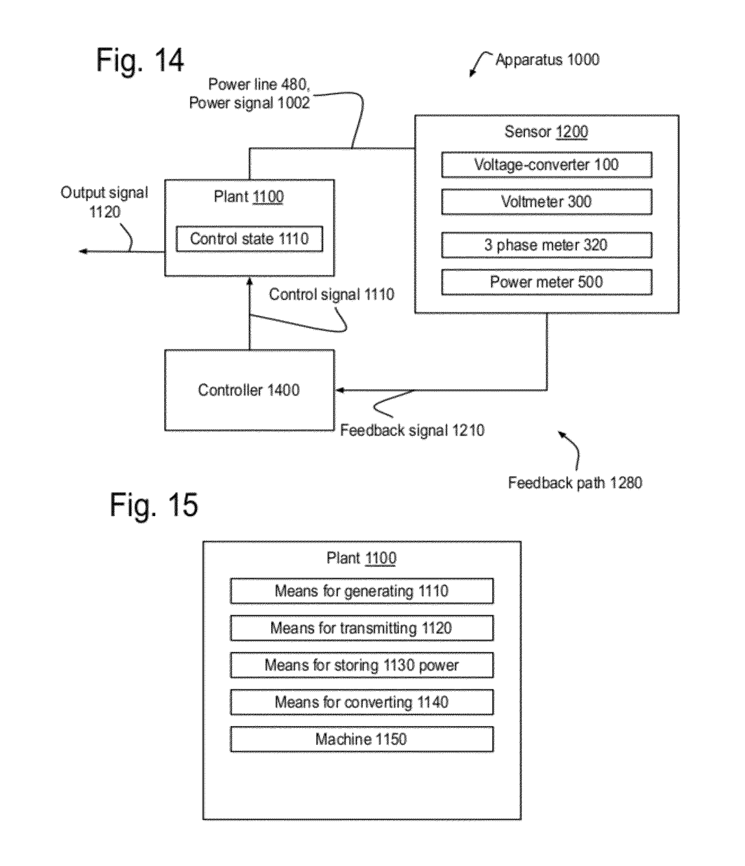

FIG. 14 shows an example of a disclosed and claimed apparatus including at least one power line 480, least one plant 1100, a controller 1400 and a feedback path 1280 coupling to the power line 480 and the controller 1400. The power line 480 may be configured to transmit a power signal 1002 with a voltage amplitude of not less than 400 Volts in a carrier frequency band FB1. The plant 1100 may be configured to respond to at least one control state 1110 to generate at least one output signal 1120. The control state 1110 and/or the output signal 1120 may include the power line 480.

The feedback path 1280 includes at least one sensor 1200 coupled to the power line 480 and configured to respond to the power signal 1002 to generate a feedback signal 1210 presented to the controller 1400. The sensor 1200 may include the voltage-converter 100, the voltmeter 300, the power meter 500 and/or the three-phase meter 320. The controller 1400 may be further configured to respond to the feedback signal 1210 to at least partly generate the control signal 1110 for the plant.

The feedback signal 1210 may be based upon at least one of the low-voltage signal 122, the digital sample 202, the digital reconstruction 204, the voltage estimate 204-V, the current estimate 204-I, the phase estimate 204-phase, the power estimate 204-power and/or one or more of the parameters.

FIG. 15 shows the plant 1100 may be configured to perform one or more of the following: Generate the power signal 1002 to drive the power line 480 by including at least one means for generating 1110 the power signal 1002. Transmit the power signal 1002 on the power line 480 by including at least one means for transmitting 1120. Store power, possibly as part of the control state 1110, from the power signal 1002 on the power line 480 by including at least one means for storing 1130 power. Convert the power signal 1002 by including at least one means for converting 1140. And/or use the power signal 1002 to drive at least one machine 1150.

Examples of the means for generating 1110 include but are not limited to steam or water powered turbines driving electrical generators and/or dynamos, wind power electrical generators, solar cell arrays, solar furnaces driving stirling engines, photo-voltaic arrays, fission nuclear reactors, and/or fusion nuclear reactors. Some may question the last entry, fusion reactors, but plasma bottles have been maintained for measurable time durations, and those time durations are progressively getting longer. Some experiments have generated as much power as they have used providing a first reduction to practice.

Examples of the means for transmitting 1120 may include but are not limited to the power lines 480 that may include but are not limited to transmission lines operating above 50 K Volts, distribution lines operating at lower voltages, the coils of inductive devices such as transformers and isolation circuitry as well as possibly switches to control the power lines, coils, transformers and isolation circuitry.

Examples of the means for storing 1130 power may include but are not limited to battery packs, fly wheels, and potential energy batteries storing power by displacing water to a height.

Examples of the means for converting 1140 may include but are not limited to transformers and inverters that may either receive the power signal 1002 and/or contribute to generating the power signal 1002.

Machines 1150 may include but are not limited to all devices on this planet or in space powered by or controlled by the power signals 1002 having a voltage amplitude 114 of at least 400 Volts at a carrier frequency 131.

The preceding embodiments provide examples of the invention and are not meant to constrain the scope of the following claims.

1. An apparatus, comprising: a voltage-converter, comprising:
an input coupling configured to receive an input signal at a carrier frequency band having
an input voltage amplitude of not less than 400 Volts;
an output coupling configured for a low voltage signal at said carrier frequency band having an output voltage amplitude of not more than the input voltage amplitude multiplied by N percent, with said N not more than ten; and
a converter body configured to generate said low voltage signal from said input signal based upon a transfer function having frequency bands including said carrier frequency band and at least one distinct frequency band, with distinct gains at said frequency bands.

2. The apparatus of claim 1, wherein said converter body comprises a first component and a second component, with said first component coupled to said input coupling and coupling through said second component to at least partly create said transfer function;
wherein said first component is configured to create a first gain in said carrier frequency band; and
wherein said second component is configured to create a second gain in said distinct frequency band.

3. The apparatus of claim 1, wherein a length of said voltage-converter is at most a scale length Lvd multiplied by said voltage amplitude of said input signal divided by 10000 volts, with said Lvd not more than a member of a group consisting of 40 centimeters (cm), 20 cm, 10 cm and 6 cm.

4. The apparatus of claim 1, further comprising: a signal processing circuit for use with said voltage-converter, comprising:
an analog to digital converter configured to receive said low voltage signal from said output coupling to create a digital sample;
a digital signal processor configured to use said digital sample to create a digital reconstruction of said input signal; and
an output device configured to present to said digital reconstruction.

5. The apparatus of claim 4, wherein said analog to digital converter is further configured to respond to said low voltage signal as a comparison to further create said low voltage signal as an in-range indication;
wherein said digital signal processor is further configured to respond to said digital sample by counting said in-range indication to create a count as at least part of said digital reconstruction; and
wherein said output device is further configured to present said count.

6. The apparatus of claim 4, wherein said digital signal processor is further configured to create said digital reconstruction based upon said transfer function used to create said low voltage signal.

7. The apparatus of claim 4, wherein said output device includes a transmitter configured to send said digital reconstruction.

8. The apparatus of claim 4, wherein said signal processing circuit further comprises a receiver coupled to said digital signal processor and said receiver is configured to present a received message to said digital signal processor; and
said digital signal processor is further configured to create said digital reconstruction in response to said received message.

9. The apparatus of claim 4, wherein said signal processing circuit further comprises
at least two voltage-converter couplings configured to receive separate of said low voltage signals from distinct instances of said voltage-converters;
an analog multiplexer coupled to said voltage-converter coupling, said analog to digital converter and a selector control, with
said analog multiplexer configured to respond to said selector control by selecting one of said separate low voltage signals to create said low voltage signal presented to analog to digital converter to further create said digital sample.

10. A method, comprising at least one of the steps of:
assembling at least two instances of at least one of said apparatus of claim 4 to create said voltage-converter with said transfer function based upon said instances;
coupling said voltage-converter and said signal processing circuit to create a voltmeter;
coupling at least three of said voltage-converters to said voltage-converter couplings included in said signal processing circuit to create a three-phase meter;
communicating from a first of said voltmeters at least one parameter of a first of said input signal to a second of said voltmeters to create a phase estimate of said input signals;
coupling a field-to-voltage-converter to said analog to digital converter as said low voltage signal in said voltmeter to create a power meter configured to create at least one of
a current estimate of a power line inductively coupled to said field-to-voltage-converter,
a phase estimate based upon said current estimate and a voltage estimate from said digital reconstruction of said input signal received by said input coupling of said voltage-converter, and
a power estimate based upon said current estimate, said phase estimate and said voltage estimate.

11. The method of claim 10, wherein said parameter is an estimate of at least one of a voltage, a current, a power, a power phase and a phasor; and
wherein said field-to-voltage-converter includes at least one of
an non-magnetically-filled Rugowsky coil coupling to an integrator to generate a voltage in response to a current flow in said power line,
an magnetically-filled Rugowsky configured to generate said voltage in response to said current flow;
a Hall effect sensor configured to respond to an electromagnetic field of said power line to generate said voltage in response to said current flow; and
said Hall effect sensor coupled to a correction loop to further generate said voltage in response to said current flow.

12. At least one said voltage-converter, said voltmeter, said three-phase meter and said power meter as products of the process of claim 10.

13. An apparatus, comprising: at least one power line configured to transmit a power signal with a carrier voltage of not less than 400 Volts in a carrier frequency band;
at least one plant configured to respond to at least one control signal to generate at least one output signal, with said power line included in at least one of said control state and said output signal;
at least one controller configured to drive at least part of said control signal for said plant;
a feedback path including at least one sensor coupled to said power line and configured to respond to said power signal to generate a feedback signal presented to said controller,
with said sensor including at least one of said voltage-converter, said voltmeter, said power meter and said three-phase meter of claim 12; and
said controller configured to respond to said feedback signal to at least partly generate said control signal for said plant.

14. A feedback path, including:
at least one sensor configured
to couple to a power line and
to respond to a power signal with a carrier voltage not less than 400 Volts in a carrier frequency band on said power line to generate a feedback signal presented to a controller,
with said sensor including at least one of said voltage-converter, said voltmeter, said power meter and said three-phase meter of claim 12; and
with at least one plant configured to respond to at least one control signal to generate at least one output, with at least one power line included in at least one of said control state and said output, and
with said controller responding to said feedback signal to generate said control signal.

15. The feedback path of claim 14, wherein said plant is configured to perform at least one of
generate said power signal to drive said power line,
transmit said power signal on said power line,
store power from said power signal on said power line,
use said power signal to drive at least one machine;
wherein said feedback signal is based upon at least one of said low-voltage signal, said digital sample, said digital reconstruction, said voltage estimate, said current estimate, said phase estimate, said power estimate, and said parameter.

16. The apparatus of claim 13, wherein said plant is configured to perform at least one of
generate said power signal to drive said power line,
transmit said power signal on said power line,
store power from said power signal on said power line,
use said power signal to drive at least one machine;
wherein said feedback signal is based upon at least one of said low-voltage signal, said digital sample, said digital reconstruction, said voltage estimate, said current estimate, said phase estimate, said power estimate, and said parameter.
